(19) United States
(12) Patent Application Publication
(10) Pub. No.: US 2024/0352588 A1
(43) Pub. Date: Oct. 24, 2024

(54) ENABLE CVD CHAMBER PROCESS WAFERS AT DIFFERENT TEMPERATURES

(71) Applicant: Applied Materials, Inc., Santa Clara, CA (US)

(72) Inventors: Peiqi WANG, Campbell, CA (US); Kai WU, Palo Alto, CA (US); Dongming IU, Union City, CA (US); Mehran BEHDJAT, Santa Clara, CA (US)

(21) Appl. No.: 18/379,028

(22) Filed: Oct. 11, 2023

Related U.S. Application Data
(60) Provisional application No. 63/460,822, filed on Apr. 20, 2023.

(51) Int. Cl. C23C 16/458; C23C 16/455

(52) U.S. Cl. CPC C23C 16/4587; C23C 16/45574; C23C 16/4586

(57) ABSTRACT

A method and apparatus for processing a substrate are described herein. The methods and apparatus described enable a chemical vapor deposition (CVD) chamber to process substrates (also referred to as wafers herein) at different temperatures. The processing chamber includes a chamber body, a substrate support disposed within the chamber body and having a top surface, a plurality of substrate lift pins disposed through the substrate support, and a shadow ring lift assembly. The shadow ring lift assembly is operable to raise and lower a shadow ring positioned above or level with the top surface of the substrate support.

### CROSS-REFERENCE TO RELATED APPLICATIONS

This application claims priority to U.S. Provisional Patent Application No. 63/460,822, filed Apr. 20, 2023, the entirety of which is herein incorporated by reference.

### BACKGROUND

### Field

Embodiments herein are directed to systems and methods used in electronic device manufacturing, and more particularly, to systems and methods used for enabling a chemical vapor deposition (CVD) chamber to process substrates (also referred to as wafers herein) at different temperatures.

### Description of the Related Art

Tungsten (W) is widely used in integrated circuit (IC) device manufacturing to form conductive features where relatively low electrical resistance and relativity high resistance to electromigration are desired. For example, tungsten may be used as a metal fill material to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below). Due to its relativity low resistivity, tungsten is also commonly used to form bit lines and word lines used to address individual memory cells in a memory cell array of a dynamic random-access memory (DRAM) device.

Tungsten may be applied to a substrate (e.g., for ICs) by a process including tungsten nucleation and bulk tungsten deposition. A nucleation process may achieve superior coverage to a desired depth of 12 μm when the substrate is at a temperature of about 300° C. Bulk tungsten deposition may result in lower internal stress, which is desirable, when the substrate is at a temperature of about 450° C. To deposit tungsten on a substrate, the substrate may undergo a nucleation process in a first chamber at a temperature of about 300° C. and then be moved to a second chamber and undergo bulk tungsten deposition in the second chamber at a temperature of about 450° C. Moving the substrate from the first chamber to the second chamber during processing negatively impacts the production rate (throughput) of the process.

Accordingly, what is needed in the art are processing systems and methods that solve the problems described above.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the description and are therefore not to be considered limiting of its scope, as the description may admit to other equally effective embodiments.

FIG. 1 schematically illustrates an embodiment of a processing system that may be used to process a substrate, according to embodiments of the disclosure.

FIG. 2 schematically illustrates the processing system of FIG. 1, with the substrate supported by the substrate support, according to embodiments of the disclosure.

FIG. 3 schematically illustrates a light pipe assembly in a processing system, according to embodiments of the disclosure.

FIG. 4 schematically illustrates a substrate support in a processing system, according to embodiments of the disclosure.

FIG. 5 illustrates a method of processing a substrate, according to embodiments of the disclosure.

FIG. 6 illustrates a method of determining a temperature of a substrate in a processing chamber, according to embodiments of the disclosure.

FIGS. 7A-7C are schematic sectional views of a portion of a substrate illustrating various aspects of the method set forth in FIG. 5.

To facilitate understanding, identical reference numerals have been used, where possible, to designate identical elements that are common to the figures. It is contemplated that elements and features of one embodiment may be beneficially incorporated in other embodiments without further recitation.

### SUMMARY

The present disclosure generally relates to systems and methods used in electronic device manufacturing, and more particularly, to systems and methods used for enabling a chemical vapor deposition (CVD) chamber to process wafers at different temperatures.

In an embodiment, a processing chamber for processing a substrate includes a chamber body, a substrate support disposed within the chamber body, a plurality of substrate lift pins disposed through the substrate support, and a shadow ring lift assembly. The substrate support has a top surface. The shadow ring lift assembly is operable to raise and lower a shadow ring positioned above or level with the top surface of the substrate support.

In an embodiment, a method of processing a substrate includes supporting the substrate at a first distance from a heater of a processing chamber, performing a nucleation process on the substrate within the processing chamber, supporting the substrate at a second distance from the heater, and performing a bulk process on the substrate within the processing chamber. The first distance is based on a first temperature of the substrate. The nucleation process is performed on the substrate while the substrate is at the first temperature within the processing chamber. The second distance is based on a second temperature of the substrate. The bulk process is performed on the substrate within the processing chamber while the substrate is at the second temperature.

In an embodiment, a method of determining a temperature of a substrate in a processing chamber includes collecting electromagnetic radiation from a top surface of a substrate support disposed in the processing chamber, sensing a temperature of the top surface of the substrate support, estimating a temperature of the top surface of the substrate support, determining a transmissivity of the light pipe, collecting electromagnetic radiation from the substrate in the processing chamber, and determining the temperature of the substrate. The electromagnetic radiation is collected from the top surface of the substrate support with a light pipe. The temperature of the top surface of the substrate support is sensed with a temperature sensor within the substrate support. The temperature of the top surface of the substrate support is estimated based on the electromagnetic radiation collected by the light pipe from the top surface of the substrate support. The transmissivity of the light pipe is determined based on a comparison of the estimated temperature of the top surface of the substrate support and the sensed temperature of the top surface of the substrate support. The electromagnetic radiation from the substrate in the processing chamber is collected with the light pipe. The temperature of the substrate is determined based on the electromagnetic radiation collected by the light pipe from the substrate and the transmissivity.

### DETAILED DESCRIPTION

The present disclosure is directed towards apparatus and methods for enabling a chemical vapor deposition (CVD) chamber (also referred to herein as a processing chamber or chamber) to process a substrate (also referred to herein as a wafer) at different temperatures. Enabling the CVD chamber to process a substrate at different temperatures improves coverage of a nucleation process on the substrate and improves a production rate (i.e., throughput) of the chamber. In embodiments described herein, a substrate is supported at a first distance from a heater of the chamber. The heater may be built into a substrate support. The first distance is determined based on a first temperature of the substrate. The first temperature may be a temperature (e.g., 300° C.) at which a nucleation process results in good coverage of the substrate. The nucleation process is then performed on the substrate. During the nucleation process, a shadow ring is positioned above the surface of the substrate. After performing the nucleation process on the substrate, the substrate support and/or the substrate may be moved so that the substrate is at a second distance from the heater (e.g., 0 mm, wherein the substrate rests on the substrate support). The substrate is heated by the heater within the substrate support to a second temperature (e.g., 450° C.) at which a bulk process results in tungsten with low internal stress being deposited on the substrate. The shadow ring is lowered close to the surface of the substrate before performing the bulk process. The bulk process may then be performed on the substrate. It is beneficial to perform the nucleation process at the first temperature and the bulk process at the second temperature within the processing chamber so that both the nucleation process and the bulk process achieve good results and the processing of the substrate is faster than the processing would be if the nucleation process and the bulk process were performed in different chambers. It is beneficial to support the substrate at the first distance from the substrate support during the nucleation process so the substrate can be at the first temperature, which is different from the temperature of the substrate support (rather than changing the temperature of the substrate support from the first temperature to the second temperature), because a thermal mass of the substrate support causes the substrate support to change temperatures slowly. It is beneficial to support a shadow ring above the surface of the substrate during the nucleation process to enable the nucleation process to occur near the beveled edge of the substrate and to prevent the shadow ring from contaminating the front surface of the substrate.

As discussed herein, the temperature of the substrate within the processing chamber may be determined by collecting electromagnetic radiation (e.g., visible or infrared (IR) light) from the substrate with a light pipe and conveying the electromagnetic radiation in an optical waveguide (e.g., an optical fiber) to a pyrometer controller. The transmissivity of the light pipe may vary over time, e.g., due to vapor deposition occurring on the end of the light pipe in the CVD chamber.

The method of determining the temperature of the substrate may include estimating a temperature of the substrate support based on electromagnetic radiation collected from the substrate support by the light pipe and comparing the estimated temperature of the substrate support with a temperature of the substrate support sensed by a sensor (e.g., a thermocouple or a resistive temperature detector (RTD)) within the substrate support.

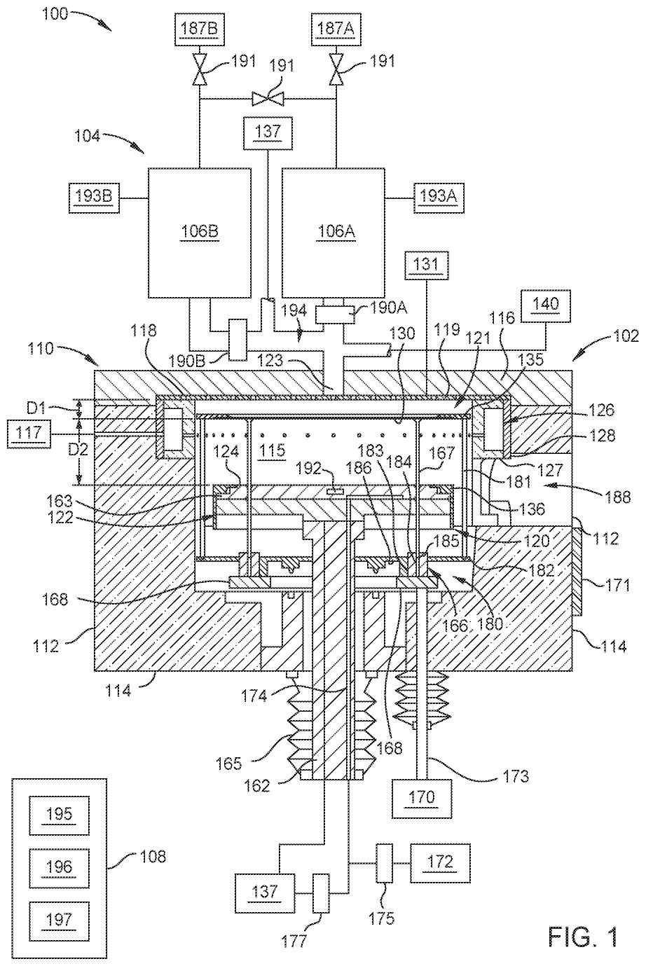

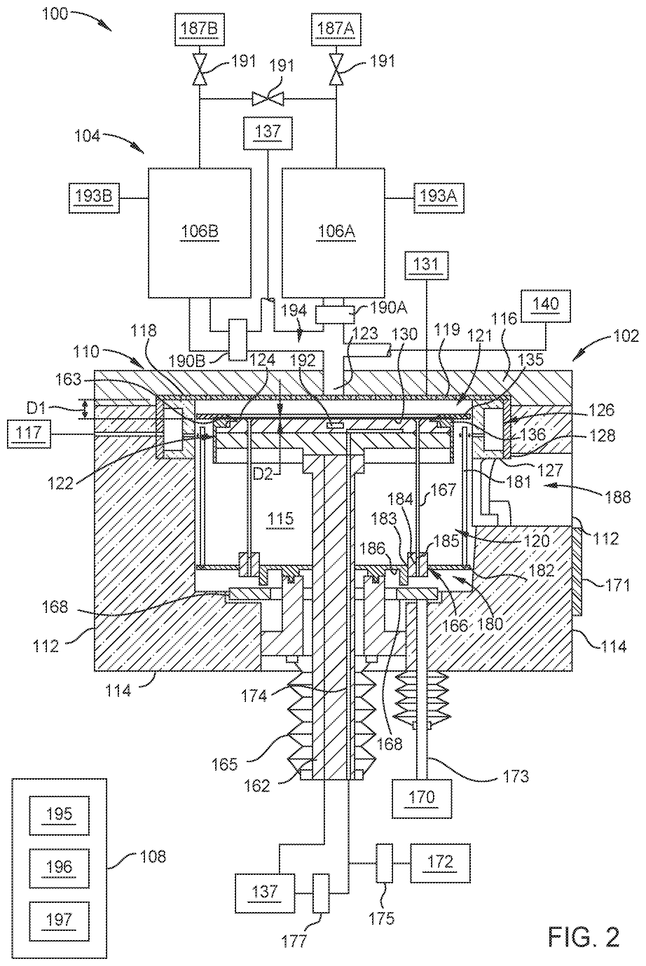

FIGS. 1 and 2 schematically illustrate an embodiment of a processing system 100 that may be used to process a substrate 130. A tungsten deposition process, such as a bottom-up tungsten gapfill substrate process, may be an example of the process described herein. Here, the processing system 100 is configured to provide different processing conditions desired for each of a nucleation process and a tungsten bulk deposition process within a single processing chamber 102, i.e., without transferring a substrate 130 between a plurality of processing chambers.

The processing system 100 includes the processing chamber 102, a gas delivery system 104 fluidly coupled to the processing chamber 102, and a system controller 108. The processing chamber 102 includes a chamber lid assembly 110, one or more sidewalls 112, and a chamber body 114, which collectively define a processing volume 115. The processing volume 115 is fluidly coupled to an exhaust 117, including one or more vacuum pumps, used to maintain the processing volume 115 at sub-atmospheric conditions and to evacuate processing gases and processing by-products therefrom.

FIG. 1 schematically illustrates the substrate 130, substrate lift pins 167, shadow ring 135, and shadow ring lift pins 167 in a first position. When the substrate 130, substrate lift pins 167, shadow ring 135, and shadow ring lift pins 167 are in the first position, the substrate 130 may be supported by the substrate lift pins 167 at a second distance D2 from the substrate support 122 (as shown in FIG. 1). The second distance D2 may be determined based on the substrate 130 being heated to a first temperature (e.g., 300° C.). When in the first position, the shadow ring 135 may be supported slightly above the substrate 130 by the substrate lift pins, so that the substrate 130 does not contact the shadow ring 135. When in the first position, a bottom surface of the shadow ring 135 may be about 0.25 mm to 0.5 mm or about 0.3 mm to 0.35 mm above a top surface of the substrate 130.

The chamber lid assembly 110 includes a lid plate 116 and a showerhead 118 coupled to the lid plate 116 to define a gas distribution volume 119 therewith. The showerhead 118 faces a substrate support assembly 120 disposed in the processing volume 115. As discussed below, the substrate support assembly 120 is configured to move a substrate support 122, and thus a substrate 130 disposed on the substrate support 122, between a raised substrate processing position (as shown in FIG. 2) and a lowered substrate transfer position (similar to the first position shown in FIG. 1, although the substrate 130 cannot be transferred while substrate lift pins 167 are raised as shown). When the substrate support assembly 120 is in the raised substrate processing position, the showerhead 118 and the substrate support 122 define a processing region 121.

The gas delivery system 104 is fluidly coupled to the processing chamber 102 through a gas inlet 123 that is disposed through the lid plate 116. Processing or cleaning gases delivered, by use of the gas delivery system 104, flow through the gas inlet 123 into the gas distribution volume 119 and are distributed into the processing region 121 through a plurality of openings in the showerhead 118.

Here, processing gases and processing by-products are evacuated radially outward from the processing region 121 through an annular channel 126 that surrounds the processing region 121. The annular channel 126 may be formed in a first annular liner 127 disposed radially inward of the one or more sidewalls 112 (as shown) or may be formed in the one or more sidewalls 112. In some embodiments, the processing chamber 102 includes one or more second liners 128, which are used to protect the interior surfaces of the one or more sidewalls 112 or chamber body 114 from corrosive gases and/or undesired material deposition.

In some embodiments, a purge gas source 137 in fluid communication with the processing volume 115 is used to flow a chemically inert purge gas, such as argon (Ar), into a region disposed beneath the substrate support 122, e.g., through the opening in the chamber body 114 surrounding a movable support shaft 162 of the substrate support 122. The purge gas may be used to create a region of positive pressure below the substrate support 122 (when compared to the pressure in the processing region 121) during substrate processing. Typically, purge gas introduced through the chamber body 114 flows upwardly therefrom and around the edges of the substrate support 122 to be evacuated from the processing volume 115 through the annular channel 126. The purge gas reduces undesirable material deposition on surfaces beneath the substrate support 122 by reducing and/or preventing the flow of material precursor gases thereinto.

Here, the substrate support assembly 120 includes the movable support shaft 162 that sealingly extends through the chamber body 114, such as being surrounded by a bellows 165 in the region below the chamber body 114, and the substrate support 122, which is disposed on the movable support shaft 162. To facilitate substrate transfer to and from the substrate support 122, the substrate support assembly 120 includes a lift pin assembly 166 comprising a plurality of substrate lift pins 167 coupled to or disposed in engagement with a lift hoop 168. The plurality of substrate lift pins 167 are movably disposed in openings formed through the substrate support 122.

When the substrate support 122 is disposed in a lowered substrate transfer position (similar to the first position shown in FIG. 1), the plurality of substrate lift pins 167 extend above a substrate receiving surface 124 (also referred to herein as a top surface) of the substrate support 122 to lift a substrate 130 therefrom and provide access to a backside (non-active) surface of the substrate 130 by a substrate handler (not shown). When the substrate support 122 is in the first position (e.g., a nucleation process position, as shown in FIG. 1), the plurality of substrate lift pins 167 are raised above the top surface 124 of the substrate support 122 to allow the substrate 130 to rest on the substrate lift pins 167.

The plurality of substrate lift pins 167 may be raised and lowered by a lift pin actuator 170. The lift pin actuator 170 may be a motor or other actuator, such as a stepping motor, a servo motor, or a direct drive motor. In some embodiments, the lift pin actuator 170 is electrically coupled to a system controller, such as the system controller 108. The lift pin actuator 170 may be coupled to the lift pin assembly via one or more pin lift shafts 173. The pin lift shafts 173 may be coupled to the lift hoop 168. In embodiments described herein, the lift hoop 168 may be a plate or disk which is supported by the one or more pin lift shafts 173 and is configured to support at least the lift pin assembly 166.

When the substrate support 122 is in the transfer position, the substrate 130 may be transferred to and from the substrate support 122 through one or more openings 188, which are selectively opened and closed by a door 171, e.g., a slit valve disposed in one of the one or more sidewalls 112. Here, one or more openings in a region surrounding the door 171, e.g., openings in a door housing, are fluidly coupled to the purge gas source 137. The purge gas is used to prevent processing and cleaning gases from contacting and/or degrading a seal surrounding the door, thus extending the useful lifetime thereof.

The substrate support 122 is configured for vacuum chucking where the substrate 130 is secured to the substrate support 122 by applying a vacuum to an interface between the substrate 130 and the substrate receiving surface 124. The vacuum is applied by use of a vacuum source 172 fluidly coupled to one or more channels 174 in the support shaft 162. The channels 174 may be connected to channels or ports formed in the substrate receiving surface 124 of the substrate support 122. In other embodiments, e.g., where the processing chamber 102 is configured for direct plasma processing, the substrate support 122 may be configured for electrostatic chucking. In some embodiments, the substrate support 122 includes one or more electrodes (not shown) coupled to a bias voltage power supply (not shown), such as a continuous wave (CW) RF power supply or a pulsed RF power supply, which supplies a bias voltage thereto.

As shown, the substrate support assembly 120 includes a heater 163.

The substrate support assembly 120 may also include a temperature sensor 192 (e.g., a thermocouple or an RTD) that may supply temperature measurements of the top surface of the substrate support 122 to a controller, such as a system controller 108.

The substrate support assembly 120 further includes a shadow ring 135, which may be used to prevent undesired material deposition on a circumferential bevel edge of the substrate 130 during processing (e.g., bulk processing as discussed herein) when the substrate 130 is positioned on the substrate support 122 (as shown in FIG. 2). During substrate transfer to and from the substrate support 122, the substrate support assembly 120 is disposed in a lowered position (similar to the first position shown in FIG. 1). When the substrate support assembly 120 is disposed in a raised or second processing position (as shown in FIG. 2, e.g., a bulk processing position), the radially outward surface of the substrate support 122 engages with the shadow ring 135 so that the shadow ring 135 circumscribes the substrate 130 disposed on the substrate support 122. Here, the shadow ring 135 is shaped so that a radially inward facing portion of the shadow ring 135 is disposed above the bevel edge of the substrate 130 when the substrate support assembly 120 is in the second processing position.

In some embodiments, the substrate support assembly 120 further includes a purge ring 136 disposed on the substrate support 122 to circumscribe the substrate 130. In those embodiments, the shadow ring 135 may be disposed on the purge ring 136 when the substrate support assembly 120 is in the second processing position. Typically, the purge ring 136 features a plurality of radially inward facing openings that are in fluid communication with the purge gas source 137. During substrate processing, a purge gas flows into an annular region defined by the shadow ring 135, the purge ring 136, the substrate support 122, and the bevel edge of the substrate 130 to prevent processing gases from entering the annular region and causing undesired material deposition on the bevel edge of the substrate 130.

In some embodiments, the processing chamber 102 is configured for direct plasma processing. In those embodiments, the showerhead 118 may be electrically coupled to a first power supply 131, such as an RF power supply, which supplies power to ignite and maintain a plasma of processing gases flowed into the processing region 121 through capacitive coupling therewith. In some embodiments, the processing chamber 102 comprises an inductive plasma generator (not shown), and a plasma is formed through inductively coupling an RF power to the processing gas.

Here, the processing system 100 may be configured to perform each of the tungsten nucleation and bulk tungsten deposition processes of a void-free and seam-free tungsten gapfill process scheme without removing the substrate 130 from the processing chamber 102. The gases used to perform the individual processes of the gapfill process scheme, and to clean residues from the interior surfaces of the processing chamber, are delivered to the processing chamber 102 using the gas delivery system 104 fluidly coupled thereto.

Generally, the gas delivery system 104 includes one or more remote plasma sources, here a first and second radical generator 106A-B, a deposition gas source 140, and a conduit system 194 fluidly coupling the radical generators 106A-B and the deposition gas source 140 to the chamber lid assembly 110. The gas delivery system 104 further includes a plurality of isolation valves, here a first and second valves 190A-B, respectively disposed between the radical generators 106A-B and the lid plate 116, which may be used to fluidly isolate each of the radical generators 106A-B from the processing chamber 102 and from one another.

Each of the radical generators 106A-B is coupled to a respective power supply 193A-B. The power supplies 193A-B are used to ignite and maintain a plasma of gases delivered to the plasma chamber volumes within the radical generators 106A-B from a corresponding first or second gas source 187A-B fluidly coupled thereto. In some embodiments, the first radical generator 106A generates radicals used in a differential inhibition process. For example, the first radical generator 106A may be used to ignite and maintain a treatment plasma from a non-halogen-containing gas mixture delivered to the first plasma chamber volume from the first gas source 187A. The second radical generator 106B may be used to generate cleaning radicals used in a chamber clean process by igniting and maintaining a cleaning plasma from a halogen-containing gas mixture delivered to the second plasma chamber volume from the second gas source 187B.

In some embodiments, the first radical generator 106A is also fluidly coupled to the second gas source 187B, which may deliver a halogen-containing conditioning gas to the first plasma chamber volume to be used in a plasma source condition process. In those embodiments, the gas delivery system 104 may further include a plurality of diverter valves 191, which are operable to direct the halogen-containing gas mixture from the second gas source 187B to the first plasma chamber volume of the radical generator 106A.

Suitable remote plasma sources which may be used for one or both of the radical generators 106A-B include radio frequency (RF) or very high radio frequency (VHRF) capacitively coupled plasma (CCP) sources, inductively coupled plasma (ICP) sources, microwave-induced (MW) plasma sources, electron cyclotron resonance (ECR) chambers, or high-density plasma (HDP) chambers.

Operation of the processing system 100 is facilitated by the system controller 108. The system controller 108 includes a programmable central processing unit, here the CPU 195, which is operable with a memory 196 (e.g., non-volatile memory) and support circuits 197. The CPU 195 is one of any form of general-purpose computer processor used in an industrial setting, such as a programmable logic controller (PLC), for controlling various chamber components and sub-processors. The memory 196, coupled to the CPU 195, facilitates the operation of the processing chamber. The support circuits 197 are conventionally coupled to the CPU 195 and comprise cache, clock circuits, input/output subsystems, power supplies, and the like, and combinations thereof coupled to the various components of the processing system 100 to facilitate control of substrate processing operations therewith.

Here, the instructions in memory 196 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

Advantageously, the processing system 100 described above may be used to perform each of a nucleation and a bulk deposition process, thus providing a single-chamber seam-free tungsten gapfill solution.

In some embodiments, when the substrate 130 is in either a first position (e.g., a nucleation process position), as shown in FIG. 1, or a second position (e.g., a bulk deposition process position), as shown in FIG. 2, a first distance D1 between the bottom surface of the showerhead 118 and the top surface of the substrate 130 is less than about 25 mm, such as less than about 20 mm, such as less than about 15 mm, such as about 5 mm to about 15 mm.

The processing system 100 includes a shadow ring lift assembly 180.

The shadow ring lift assembly 180 is integrated with the lift pin assembly 166, such that the lift hoop 168 may be detachably coupled to both the plurality of substrate lift pins 167 as well as a plurality of shadow ring lift pins 181. The shadow ring lift assembly 180 is configured to raise and lower the shadow ring 135 between or during processing operations. Both the shadow ring 135 and the substrate lift pins 167 may be raised or lowered either simultaneously or separately as described herein.

As shown in FIG. 1, the shadow ring lift assembly 180 includes the lift hoop 168, the lift pin assembly 166, the shadow ring lift pins 181, a shadow ring lift plate 186, one or more shadow ring lift arms 182 extending from the shadow ring lift plate 186, and a plurality of substrate lift pin holders 183 extending through the shadow ring lift plate 186. The plurality of substrate lift pin holders 183 are openings through the shadow ring lift plate 186 and include sidewalls extending downward from the shadow ring lift plate 186 to provide a guide for the substrate lift pins 167.

The bottom surface of each of the substrate lift pin holders 183 is coupled to and disposed on top of the lift hoop 168. In some embodiments, the substrate lift pin holders 183 are disposed through the lift hoop 168 and form openings through the lift hoop 168. In some embodiments, the substrate lift pin holders 183 are disposed both partially above and partially below the lift hoop 168, such that the substrate lift pin holders 183 are shafts disposed through the lift hoop 168. The substrate lift pin holders 183 may be mechanically coupled to each of the shadow ring lift arms 182. The shadow ring lift arms 182 extend outwardly from the shadow ring lift plate 186 and couple the shadow ring lift pins 181 to the shadow ring lift plate 186 and the substrate lift pin holders 183 and subsequently enable motion of the shadow ring lift pins 181 when the lift hoop 168 moves in an upward and a downward motion.

The lift hoop 168 may be coupled to the one or more pin lift shafts 173 and the lift pin actuator 170 to enable vertical motion of the lift hoop 168. The lift hoop 168 may then impart motion to one or both of the lift pin assembly 166 or the shadow ring lift assembly 180. The lift pin actuator 170 may be a motor or a pneumatic actuator. The system controller 108 may control the lift pin actuator 170 to position the lift hoop 168, the substrate lift pins 167, the shadow ring lift pins 181, and the substrate lift pin holder 183 as described with respect to FIGS. 1-2. In some embodiments, the shadow ring lift plate 186 is coupled to and disposed on the lift hoop 168 and the bottom surface of each of the substrate lift pin holders 183 does not contact the lift hoop 168.

The lift pin assembly 166 includes a lift pin base 185 coupled to each lift pin 167. The lift pin 167 is configured to extend through a portion of the substrate support 122 to contact a backside of the substrate 130. The lift pin 167 is configured to rest in a slot disposed within the substrate support 122. The bottom distal end of the lift pin 167 is coupled to the lift pin base 185. The lift pin base 185 may be a cylindrical base and is configured to have a substantially similar diameter to a hollow inner surface 184 of each of the substrate lift pin holders 183. Each of the substrate lift pin holders 183 have the hollow inner surface 184 to enable the lift pin base 185 to move therein. In some embodiments, the substrate lift pin holders 183 surround the entire circumference of the lift pin base 185. In other embodiments, the substrate lift pin holders 183 partially surround the circumference of the lift pin base 185.

The substrate processing system includes the opening 188 disposed through the side of the processing chamber 102. The opening 188 may include a slit valve or a door 171 disposed therein. Although not apparent from FIGS. 1 and 2, it should be noted that the shadow ring lift pins 181 are offset from the opening 188 to allow movement of the substrate 130 into and out of the processing chamber 102.

While in the substrate transfer position, the lift hoop 168 is in contact with the lift pin base 185 as well as the substrate lift pin holder 183. The lift hoop 168 is a ring which connects to the one or more pin lift shafts 173 and is used as a base for lifting the substrate as well as the shadow ring 135. While in the substrate transfer position, the first distance D1 between the bottom surface of the showerhead 118 and the top surface of the substrate support 122 is about 40 mm to about 80 mm, such as about 50 mm to about 70 mm, such as about 55 mm to about 65 mm. While in the substrate transfer position, the shadow ring 135 and the tops of the shadow ring lift pins 181 may be in a variety of positions above the substrate support 122 and the substrate 130. As described herein, the height of the shadow ring 135 is at least partially dependent upon the position of the substrate lift pins 167 during transfer of the substrate 130 into and out of the processing region 121.

While in the substrate transfer position, the shadow ring lift pins 181 contact a bottom surface of the shadow ring 135. Each of the shadow ring lift pins 181 are disposed radially outward of the substrate 130 and disposed at obtuse angles around the circumference of the substrate support 122 to enable the substrate 130 to pass therebetween and into the opening 188 during substrate transfer.

As shown in FIG. 2, the shadow ring lift assembly 180 and the lift pin assembly 166 are in a second position. While in the second position, the lift hoop 168 is in a position where the shadow ring 135 is supported by the purge ring 136 above the shadow ring lift pins 181, while the substrate lift pins 167 are in a lowered position. The lowered position of the substrate lift pins 167 is a position wherein the tops of the substrate lift pins 167 are level with or disposed below a substrate support surface and the substrate 130. The substrate support 122 is disposed in a raised position while in the second position, such that a substrate receiving surface 124 of the substrate support 122 is disposed a second distance D1 from the bottom surface of the showerhead 118. While in the second position, the second distance D1 is less than about 25 mm, such as less than about 20 mm, such as less than about 15 mm, such as about 10 mm to about 15 mm.

While in the second position, as shown in FIG. 2, the substrate lift pins 167 are in a free-hanging state from the substrate support 122, such that the lift pin bases 185 do not contact the top surface of the lift hoop 168, but are still disposed within the hollow inner surface 184 of the substrate lift pin holders 183. A gap may be disposed between the lift pin bases 185 and the lift hoop 168, such that the substrate lift pins 167 are at least partially disposed within the substrate lift pin holders 183, but are not mechanically supported by the lift hoop 168.

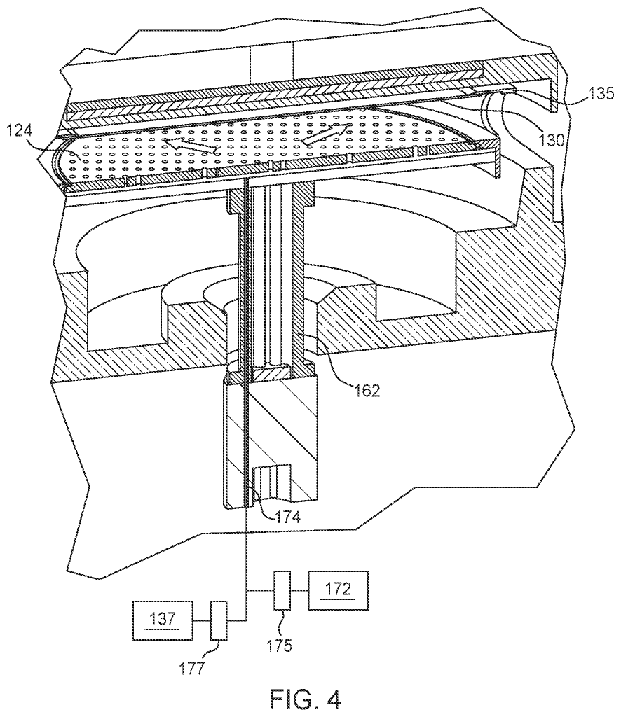

As shown in FIG. 2, both the shadow ring 135 and the substrate lift pins 167 are shown in the second position, such that the shadow ring 135 is configured to protect the substrate 130 during a deposition process. The shadow ring 135 is in a lower position than in the first position of FIG. 1, such that the lift hoop 168 and the substrate lift pin holder 183 are lowered. The substrate lift pins 167 are similarly free-hanging from the substrate support 122 as in the treatment position of FIG. 4B. The substrate lift pins 167 may not move while the shadow ring 135 is lowered from the first position to the second position or while the shadow ring 135 is raised from the second position to the first position.

While in the second position, the shadow ring lift pins 181 may still be in contact with the bottom of the shadow ring 135 or the shadow ring lift pins 181 may be separated from the shadow ring 135 (as shown in FIG. 2). In some embodiments, the shadow ring lift plate 186 and/or the shadow ring lift arms 182 are disposed on top of and contacting a lower wall 189 of the chamber body 114 while in the second position. Contacting the lower wall 189 of the chamber body 114 may cause the shadow ring lift plate 186 to disengage from the lift hoop 168.

The positioning of each of the shadow ring lift plate 186, the lift hoop 168, and the lift pin bases 185 may be adjusted relative to the length of each of the substrate lift pins 167 and the shadow ring lift pins 181 as well as the desired second distance D2 during treatment and deposition on the substrate 130.

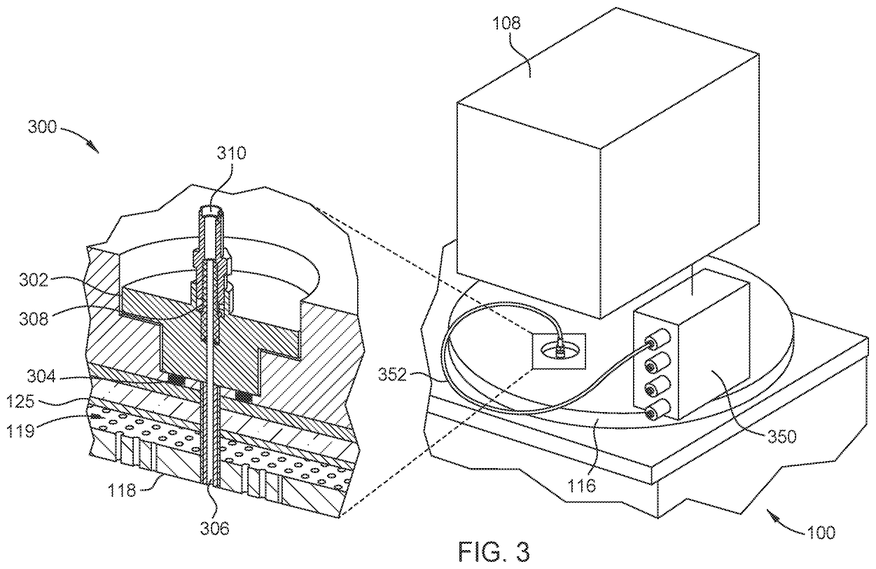

Referring back to FIG. 1, during processing of the substrate 130 within the processing system 100, the substrate 130 may be supported by the substrate lift pins 167 at a second distance D2 from the substrate support 122 (as shown in FIG. 1). The second distance D2 may be determined based on the substrate 130 being heated to a first temperature (e.g., 300° C.). The showerhead 118 and lid plate 116 may be maintained at a temperature (e.g., 80 to 100° C.) lower than a temperature (e.g., 450° C.) of the substrate support 122, and the substrate 130 may be heated to and maintained at the first temperature as a result of radiative heat transfer from the substrate support 122 to the substrate 130 and radiative heat transfer from the substrate 130 to the showerhead 118. The temperature of the substrate 130 may be determined based on electromagnetic radiation (e.g., IR rays) from the substrate 130 collected by a light pipe assembly 300 shown in FIG. 3.

While the substrate 130 is supported by the substrate lift pins 167, as shown in FIG. 1, and undergoing processing, purge gas may be supplied from the purge gas source 137 to the channels 174 and from the channels 174 to ports or channels in the top surface of the substrate support 122, as shown in FIG. 4. The purge gas may act to prevent process gases (also referred to herein as precursors, deposition gases, and treatment gases) supplied via the showerhead 118 (i.e., from above the substrate) from contacting and reacting with the back surface of the substrate 130.

FIG. 2 shows the substrate 130 at the second distance D2 (e.g., 0 mm) from the substrate receiving surface 124 of the substrate support 122 within the processing system 100. As shown in FIG. 2, when the substrate 130 is at the second distance D2 from the substrate receiving surface 124, the lift pins 167 may recede beneath the substrate receiving surface 124 to enable the substrate 130 to rest upon the substrate receiving surface. The second distance D2 may be determined based on the substrate 130 being heated to a second temperature (e.g., 450° C.). As in FIG. 1, the showerhead 118 and lid plate 116 may be maintained at a temperature (e.g., 80 to 100° C.) lower than a temperature (e.g., 450° C.) of the substrate support 122. The substrate 130 may be heated to and maintained at the second temperature as a result of radiative heat transfer from the substrate support 122 to the substrate 130, conductive heat transfer from the substrate support 122 to the substrate 130, and radiative heat transfer from the substrate 130 to the showerhead 118. The temperature of the substrate 130 may be determined based on electromagnetic radiation (e.g., IR rays) from the substrate 130 collected by a light pipe assembly 300 shown in FIG. 3.

FIG. 3 schematically illustrates a light pipe assembly 300 in a processing system 100. The light pipe assembly 300 includes a light pipe support 302, a light pipe support seal 304, a light pipe 306, a light pipe seal 308, and an optical waveguide plug 310. The light pipe support 302 is attached (e.g., by screws) to the lid plate 116 of the processing system 100. The light pipe support 302 has an elongated central structure that is installed through through-holes of the lid plate 116, perforated blocker plate 125 (if present), and showerhead 118. The light pipe support 302 has a through-hole in the elongated structure in which the light pipe 306 is installed. Thus, one end of the light pipe 306 is exposed to the interior of the processing chamber 102. The other end of the light pipe 306 is exposed to the exterior of the processing chamber 102. The light pipe 306 is made of a material that is translucent to most IR and optical wavelengths of light. The optical waveguide plug 310 is installed in the light pipe support 302 over the end of the light pipe 306 that is exposed to the exterior of the processing chamber 102. The light pipe support seal 304 is installed under the light pipe support 302 and is compressed between the light pipe support 302 and the lid plate 116 to prevent gases from leaking under the light pipe support 302 and into or out of the interior of the processing chamber 102. The light pipe seal 308 is installed around the light pipe 306 where the light pipe 306 exits the light pipe support 302 to the exterior of the processing chamber 102. The light pipe seal 308 may prevent gases from leaking through the through-hole of the light pipe support 302 into or out of the interior of the processing chamber 102. The optical waveguide plug 310 is configured to enable an optical waveguide 352 (e.g., an optical fiber) to be connected with the light pipe 306 so that electromagnetic radiation (e.g., light) from the interior of the processing chamber 102 can be conveyed to a pyrometer controller 350. The pyrometer controller 350 receives the electromagnetic radiation conveyed by the optical waveguide 352 and determines a temperature of a substrate 130 shown in FIGS. 1 and 2, a substrate support 122 shown in FIGS. 1 and 2, or some other item in the field of view of the light pipe 306 (i.e., in the interior of the processing chamber 102). The pyrometer controller 350 may send a signal indicating the detected temperature to a system controller 108 of the processing system 100.

In embodiments of the present disclosure, CVD chamber (e.g., processing chamber 102) components may be or may become coated with substrate outgassing and process residue. Such a coating may interfere with the collection of electromagnetic radiation from the interior of the processing chamber 102 by the light pipe 306.

In embodiments of the present disclosure, a controller (e.g., system controller 108, pyrometer controller 350, or a combination thereof) may estimate a transmission loss in the light pipe 306 based on a radiation signal to the controller and an accurate temperature measurement. The estimated transmission loss may then be used by the controller in determining a temperature measurement of a substrate 130 within the processing chamber 102.

For example, the controller (e.g., system controller 108, pyrometer controller 350, or a combination thereof) may estimate a temperature of the heater 163 and/or the substrate receiving surface 124 of the substrate support 122 based on electromagnetic radiation collected by the light pipe 306 and compare that estimated temperature to a measurement of the temperature of the heater 163 and/or the substrate receiving surface 124 of the substrate support 122 made by the temperature sensor 192 within the substrate support 122. The controller may estimate the transmission loss in the light pipe 306 based on the comparison of the estimated temperature to the measured temperature.

In embodiments of the present disclosure, an operator or the controller (e.g., system controller 108, pyrometer controller 350, or a combination thereof) may perform the following algorithm:
1. Measure (e.g., with a pyrometer) a temperature of the heater 163 or the substrate receiving surface 124 based on electromagnetic radiation collected by the light pipe 306 when the light pipe 306 has not been exposed to process gases (e.g., the light pipe 306 is newly installed and/or is in pristine condition).
2. Calculate an effective emissivity εₑ of the heater 163 or the substrate receiving surface 124, based on the measured temperature.
3. During processing in the processing system 100, before each substrate 130 is transferred into the processing chamber 102:
   a. estimate (e.g., with a pyrometer) a temperature of the heater 163 or the substrate receiving surface 124, based on electromagnetic radiation collected by the light pipe 306;
   b. sense (e.g., with the temperature sensor 192) the temperature of the heater 163 or the substrate receiving surface 124;
   c. calculate a new effective emissivity εₑ′ of the heater 163 or the substrate receiving surface 124, based on a comparison of the estimated temperature and the sensed temperature; and
   d. calculate a transmissivity, μ, of the light pipe 306, as μ=εₑ′/εₑ
4. During processing in the processing system 100, after each substrate 130 is transferred into the processing chamber 102 and before that substrate 130 is removed from the processing chamber:
   a. estimate (e.g., with a pyrometer) a temperature of the substrate 130, based on electromagnetic radiation collected by the light pipe 306; and
   b. determine the temperature of the substrate 130, based on the estimated temperature and the calculated transmissivity, y, of the light pipe 306.
      In embodiments of the present disclosure, the operator or the controller may repeat #4 of the algorithm above multiple times, when it is desirable to perform multiple processing operations at different temperatures on the substrate 130.

FIG. 4 schematically illustrates the substrate support 122 in the processing system 100. As illustrated in FIG. 4, the substrate 130 is in a first position, similar to the substrate 130 as shown in FIG. 1. As previously described, when the substrate is in the first position and processing is occurring in the processing chamber 102, purge gas (represented by the arrows in FIG. 4) may be supplied from the purge gas source 137 via the channels 174 to ports or channels in the substrate receiving surface 124 of the substrate support 122. When purge gas is supplied to the channels 174, the system controller 108 (not shown in FIG. 4, see FIGS. 1-2) may cause a valve 175 to close and a valve 177 to open to enable the purge gas to flow into the channels 174. When the substrate 130 is vacuum chucked to the substrate support 122, the system controller may cause the valve 177 to close and the valve 175 to open to supply vacuum to the channels 174 and vacuum chuck the substrate 130 to the substrate support 122.

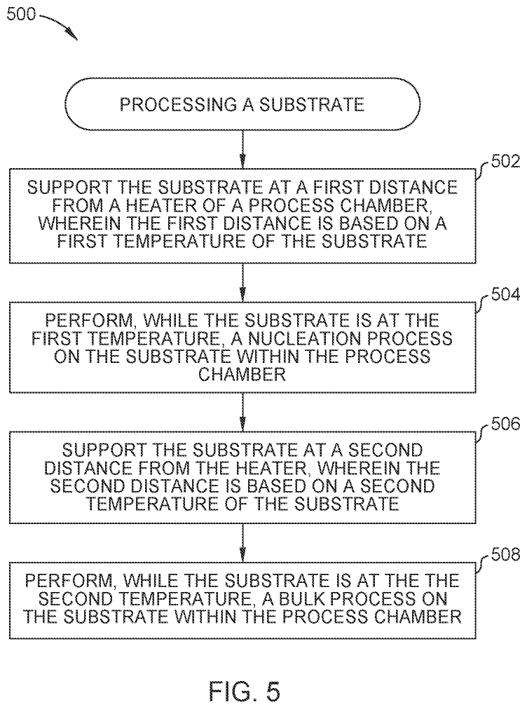

FIG. 5 is a flowchart of a method 500 for processing a substrate, such as the substrate 130 described in this disclosure. An operator or a controller (e.g., the system controller 108 of FIGS. 1-2) may control each operation of the method.

Operation 502 includes supporting the substrate at a first distance from a heater of a processing chamber, wherein the first distance is based on a first temperature of the substrate. For example and with reference to FIG. 1, an operator or a controller (e.g., the system controller 108 of FIGS. 1-2) causes the substrate lift pins 167 to move to support the substrate 130 at a first distance (e.g., D2 in FIG. 1) from the heater 163 of the processing chamber 102, wherein the first distance is based on a first temperature (e.g., 300° C.) of the substrate 130.

Operation 504 includes performing, while the substrate is at the first temperature, a nucleation process on the substrate within the processing chamber. Continuing the example from above, an operator or a controller (e.g., the system controller 108 from FIGS. 1-2) causes the processing system 100 to perform a nucleation process on the substrate 130 within the processing chamber 102.

Operation 506 includes supporting the substrate at a second distance from the heater, wherein the second distance is based on a second temperature of the substrate. Continuing the example from above, an operator or a controller (e.g., the system controller 108 of FIGS. 1-2) causes the substrate support 122 to support (e.g., by causing the support shaft 162 to raise the substrate support 122 and causing the lift pin actuator 170 to lower the lift hoop 168) the substrate 130 at a second distance (e.g., D2 in FIG. 2) from the heater 163, wherein the second distance is based on a second temperature (e.g., 450° C.) of the substrate 130.

Operation 508 includes performing, while the substrate is at the second temperature, a bulk process on the substrate within the processing chamber. Continuing the example from above, an operator or a controller (e.g., the system controller 108 from FIGS. 1-2) causes the processing system 100 to perform, while the substrate 130 is at the second temperature (e.g., 450° C.), a bulk process on the substrate 130 within the processing chamber 102.

In some embodiments, the second distance is 0 millimeters (mm), and the second temperature of the substrate is approximately equal to a temperature of the heater.

In some embodiments, the method 500 further includes supporting, with one or more shadow ring lift pins, a shadow ring of the processing chamber above the substrate while performing the nucleation process on the substrate.

In some embodiments, the first temperature is between 285° C. and 315° C.

In some embodiments, the first temperature is between 298° C. and 302° C.

In some embodiments, the second temperature is between 435° C. and 465° C.

In some embodiments, the second temperature is between 448° C. and 452° C.

In some embodiments, the method 500 further includes supporting a purge ring with the heater. In one embodiment, the method 500 further includes supporting, with the purge ring, a shadow ring of the processing chamber while performing the bulk process.

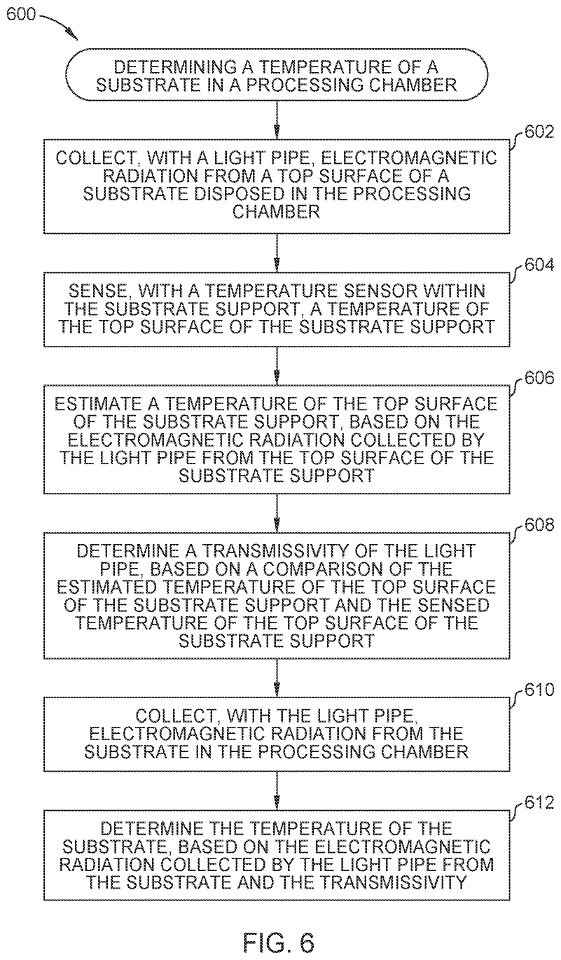

FIG. 6 is a flowchart of a method 600 for determining a temperature of a substrate, such as substrate 130, in a processing chamber, such as processing chamber 102, as described in this disclosure. An operator or a controller (e.g., the system controller 108 of FIGS. 1-2) may control each operation of the method.

Operation 602 includes collecting, with a light pipe, electromagnetic radiation from a top surface of a substrate support disposed in the processing chamber. For example and with reference to FIGS. 1-3, an operator or a controller (e.g., the system controller 108 of FIGS. 1-2, the pyrometer controller 350 of FIG. 3, or a combination thereof) collects, with the light pipe 306, electromagnetic radiation (e.g., visible and/or IR light) from a top surface (e.g., substrate receiving surface 124 of FIGS. 1-2) of the substrate support 122 disposed in the processing chamber 102.

Operation 604 includes sensing, with a temperature sensor within the substrate support, a temperature of the top surface of the substrate support. Continuing the example from above, an operator or a controller (e.g., the system controller 108 from FIGS. 1-2, the pyrometer controller 350 of FIG. 3, or a combination thereof) senses, with the temperature sensor 192 within the substrate support 122, a temperature (e.g., 450° C.) of the top surface (e.g., substrate receiving surface 124 of FIGS. 1-2) of the substrate support 122.

Operation 606 includes estimating a temperature of the top surface of the substrate support, based on the electromagnetic radiation collected by the light pipe from the top surface of the substrate support. Continuing the example from above, an operator or a controller (e.g., the system controller 108 of FIGS. 1-2, the pyrometer controller 350 of FIG. 3, or a combination thereof) estimates a temperature (e.g., 450° C.) of the top surface (e.g., substrate receiving surface 124 of FIGS. 1-2) of the substrate support 122, based on the electromagnetic radiation collected by the light pipe 306 from the top surface (e.g., substrate receiving surface 124 of FIGS. 1-2) of the substrate support 122.

Operation 608 includes determining a transmissivity of the light pipe, based on a comparison of the estimated temperature of the top surface of the substrate support and the sensed temperature of the top surface of the substrate support. Continuing the example from above, an operator or a controller (e.g., the system controller 108 from FIGS. 1-2, the pyrometer controller 350 of FIG. 3, or a combination thereof) determines a transmissivity (e.g., 1.0) of the light pipe 306, based on a comparison of the estimated temperature (e.g., 450° C.) of the top surface (e.g., substrate receiving surface 124 of FIGS. 1-2) of the substrate support 122 and the sensed temperature (e.g., 450° C.) of the top surface (e.g., substrate receiving surface 124 of FIGS. 1-2) of the substrate support 122.

Operation 610 includes collecting, with the light pipe, electromagnetic radiation from the substrate in the processing chamber. Continuing the example from above, an operator or a controller (e.g., the system controller 108 of FIGS. 1-2, the pyrometer controller 350 of FIG. 3, or a combination thereof) collects, with the light pipe 306, electromagnetic radiation (e.g., visible and/or IR light) from the substrate 130 in the processing chamber 102.

Operation 612 includes determining the temperature of the substrate, based on the electromagnetic radiation collected by the light pipe from the substrate and the transmissivity. Continuing the example from above, an operator or a controller (e.g., the system controller 108 from FIGS. 1-2, the pyrometer controller 350 of FIG. 3, or a combination thereof) determines the temperature (e.g., 300° C.) of the substrate 130, based on the electromagnetic radiation (e.g., visible and/or IR light) collected by the light pipe 306 from the substrate 130 and the transmissivity (e.g., 1.0).

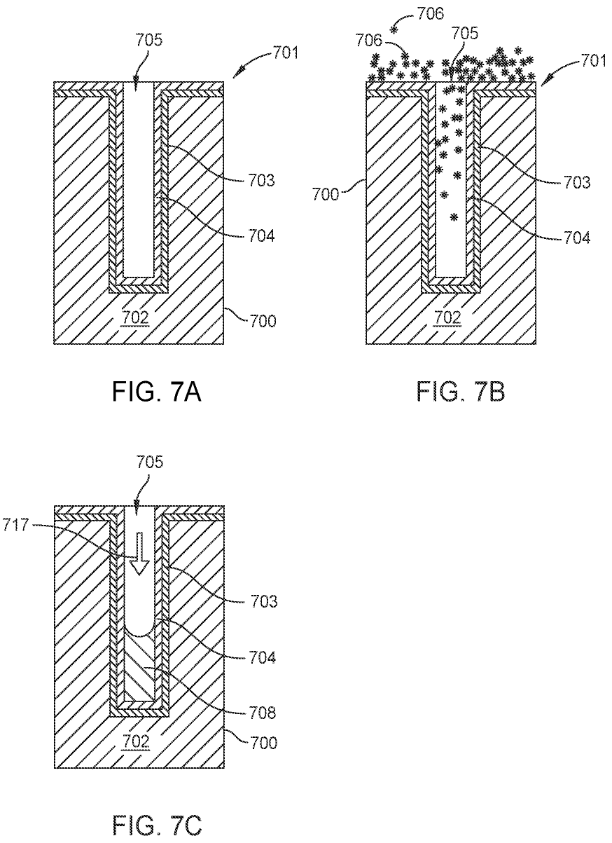

FIG. 7A schematically illustrates a portion of an exemplary substrate 700 having a nucleation layer 704 formed thereon. The exemplary substrate 700 may be an example of the substrate 130 shown in FIGS. 1, 2, and 4. The substrate 700 features a patterned surface 701 comprising a dielectric material layer 702 having a plurality of openings 705 (one shown) formed therein. In some embodiments, the plurality of openings 705 comprises one or a combination of high aspect ratio via or trench openings having a width of about 1 μm or less, such as about 800 nm or less, or about 500 nm or less, and a depth of about 2 μm or more, such as about 3 μm or more, or about 4 μm or more. In some embodiments, individual ones of the openings 705 may have an aspect ratio (depth to width ratio) of about 5:1 or more, such as about 10:1 or more, 15:1 or more, or between about 10:1 and about 40:1, such as between about 15:1 and about 40:1. As shown, the patterned surface 701 includes a barrier or adhesion layer 703, e.g., a titanium nitride (TiN) layer, deposited on the dielectric material layer 702 to conformally line the openings 705 and facilitate the subsequent deposition of the tungsten nucleation layer 704. In some embodiments, the adhesion layer 703 is deposited to a thickness of between about 2 angstroms (Å) and about 100 Å.

In some embodiments, the adhesion layer 703 and the nucleation layer 704 may be sequentially deposited in the same processing chamber 102. In some embodiments, the adhesion layer 703 functions as a nucleation layer enabling subsequent bulk tungsten deposition thereon.

In some embodiments, the nucleation layer 704 is deposited using an atomic layer deposition (ALD) process. Typically, the ALD process includes repeating cycles of alternately exposing the substrate 700 to a tungsten-containing precursor, exposing the substrate 700 to a reducing agent, and purging the processing region 121 between the alternating exposures. Examples of suitable tungsten-containing precursors (also referred to herein as process gases or deposition gases) include tungsten halides, such as tungsten hexafluoride (WF₆), tungsten hexachloride (WCl₆), or combinations thereof. Examples of suitable reducing agents include hydrogen gas (H₂), boranes, e.g., B₂H₆, and silanes, e.g., SiH₄, Si₂H₆, or combinations thereof. In some embodiments, the tungsten-containing precursor comprises WF₆, and the reducing agent comprises B₂H₆, SiH₄, or a combination thereof. In some embodiments, the tungsten-containing precursor comprises an organometallic precursor and/or a fluorine-free precursor, e.g., MDNOW (methylcyclopentadienyl-dicarbonylnitrosyl-tungsten), EDNOW (ethylcyclopentadienyl-dicarbonylnitrosyl-tungsten), tungsten hexacarbonyl (W(CO)6), or combinations thereof.

During a nucleation process, the processing volume 115 is typically maintained at a pressure of less than about 120 Torr, such as of between about 900 mTorr and about 120 Torr, between about 1 Torr and about 100 Torr, or for example, between about 1 Torr and about 50 Torr. Exposing the substrate 700 to the tungsten-containing precursor includes flowing the tungsten-containing precursor into the processing region 121 from the deposition gas source 140 at a flow rate of more than about 10 sccm, such as between about 10 sccm and about 1000 sccm, such as between about 10 sccm and about 750 sccm, or between about 10 sccm and about 500 sccm. Exposing the substrate 700 to the reducing agent includes flowing the reducing agent into the processing region 121 from the deposition gas source 140 at a flow rate of between about 10 sccm and about 1000 sccm, such as between about 10 sccm and about 750 sccm. It should be noted that the flow rates for the various deposition and treatment processes described herein are for a processing system 100 configured to process a 300 mm diameter substrate. Appropriate scaling may be used for processing systems configured to process different-sized substrates.

Here, the tungsten-containing precursor and the reducing agent are each flowed into the processing region 121 for a duration of between about 0.1 seconds and about 10 seconds, such as between about 0.5 seconds and about 5 seconds. The processing region 121 may be purged between the alternating exposures by flowing an inert purge gas, such as argon (Ar), into the processing region 121 for a duration of between about 0.1 seconds and about 10 seconds, such as between about 0.5 seconds and about 5 seconds. The purge gas may be delivered from the deposition gas source 140 or from the bypass gas source 138. Typically, the repeating cycles of the nucleation process continue until the nucleation layer 704 has a thickness of between about 10 Å and about 200 Å, such as between about 10 Å and about 150 Å, or between about 20 Å and about 150 Å. Presence of a shadow ring (e.g., shadow ring 135) adjacent to the substrate 700 may reduce the deposition rater near the beveled edge of the substrate 700.

The nucleation layer 704 may be treated to inhibit tungsten deposition on a field surface of the substrate 700 and to form a differential inhibition profile in the plurality of openings 705 by use of a differential inhibition process. Typically, forming the differential inhibition profile includes exposing the nucleation layer 704 to the activated species of a treatment gas, e.g., the treatment radicals 706 shown in FIG. 7B. Suitable treatment gases that may be used for the inhibition process include N₂, H₂, NH₃, NH₄, O₂, CH₄, or combinations thereof. In some embodiments, the treatment gas comprises nitrogen, such as N₂, H₂, NH₃, NH₄, or a combination thereof, and the activated species comprise nitrogen radicals, e.g., atomic nitrogen. In some embodiments, the treatment gas is combined with an inert carrier gas, such as Ar, He, or a combination thereof, to form a treatment gas mixture.

The activated nitrogen species (treatment radicals 706) may be incorporated into portions of the nucleation layer 704 by adsorption of the activated nitrogen species and/or by reaction with the metallic tungsten of the nucleation layer 704 to form a tungsten nitride (WN) surface. The adsorbed nitrogen and/or nitrided surface of the tungsten nucleation layer 704 may delay (inhibit) further tungsten nucleation and thus subsequent tungsten deposition thereon.

Generally, diffusion of the treatment radicals 706 into the plurality of openings 705 may be controlled to cause a desired inhibition gradient within the feature openings 705. Here, diffusion of the treatment radicals 706 is controlled so that the tungsten growth inhibition effect decreases on the walls of the openings 705 with increasing distance from the field of the patterned surface 701 (FIGS. 7B-7C). As a result, tungsten nucleation is more easily established at locations at or near the bottom of the feature, and once established, tungsten growth (deposition of the gapfill material 708) within the openings 705 accelerates from the point of nucleation (e.g., from regions of no or low inhibition at the bottom of the opening 705) to provide for a bottom-up seamless tungsten gapfill. The direction of the inhibition gradient, from regions of higher inhibition to regions of no or lower inhibition, is shown by arrow 717 shown in FIG. 7C. Diffusion of the treatment radicals 706 into the openings 705 typically depends, at least in part, on the size and aspect ratios of the openings 705 and may be adjusted by controlling inter alia, the energy, flux, and, in some embodiments, the directionality of the treatment radicals 706 at the patterned surface 701.

In some embodiments, exposing the nucleation layer 704 to the treatment radicals 706 includes forming a treatment plasma of a substantially halogen-free treatment gas mixture using the first radical generator 106A and flowing the effluent of the treatment plasma into the processing region 121. In some embodiments, a flow rate of the treatment gas mixture into the first radical generator 106A, and thus the flow rate of the treatment plasma effluent into the processing region 121, is between about 1 sccm and about 3000 sccm, such as between about 1 sccm and about 2500 sccm, between about 1 sccm and about 2000 sccm, between about 1 sccm and about 1000 sccm, between about 1 sccm and about 500 sccm, between about 1 sccm and about 250 sccm between about 1 sccm and about 100 sccm, or between about 1 sccm and about 75 sccm, for example, between about 1 sccm and about 50 sccm.

In some embodiments, a concentration of the substantially halogen-free treatment gas in the treatment gas mixture is between about 0.5 vol. % and about 50 vol. %, such as between about 0.5 vol. % and about 40 vol. %, between about 0.5 vol. % and about 30 vol. %, about 0.5 vol. % and about 20 vol. %, or, for example, between about 0.5 vol. % and about 10 vol. %, such as between about 0.5 vol. % and about 5 vol. %.

In some embodiments, e.g., where the substantially halogen-free treatment gas comprises N₂, NH₃, and/or NH₄, the first radical generator 106A may be used to activate between about 0.02 mg and about 150 mg of atomic nitrogen during an inhibition treatment process for a 300 mm diameter substrate, such as between about 0.02 mg and about 150 mg, or between about 0.02 mg and about 100 mg, between about 0.1 mg and about 100 mg, between about 0.1 mg and about 100 mg, or between about 1 mg and about 100 mg. In some embodiments, the first radical generator 106A may be used to activate about 0.02 mg of atomic nitrogen or more during an inhibition treatment process for a 300 mm diameter substrate, such as about 0.2 mg or more, about 0.4 mg or more, about 0.6 mg or more, about 0.8 mg or more, about 1 mg or more, about 1.2 mg or more, about 1.4 mg or more, about 1.6 mg or more, about 1.8 mg or more, about 2 mg or more, about 2.2 mg or more, about 2.4 mg or more, about 2.6 mg or more, about 2.8 mg, or about 3 mg or more. Appropriate scaling may be used for processing systems configured to process different sized substrates.

In other embodiments, the treatment radicals 706 may be formed using a remote plasma (not shown) which is ignited and maintained in a portion of the processing volume 115 that is separated from the processing region 121 by the showerhead 118, such as between the showerhead 118 and the lid plate 116. In those embodiments, the activated treatment gas may be flowed through an ion filter to remove substantially all ions therefrom before the treatment radicals 706 reach the processing region 121 and the surface of the substrate 700. In some embodiments, the showerhead 118 may be used as the ion filter. In other embodiments, a plasma used to form the treatment radicals is an in-situ plasma formed in the processing region 121 between the showerhead 118 and the substrate 700. In some embodiments, e.g., when using an in-situ treatment plasma, the substrate 700 may be biased to control the directionality and/or accelerate ions formed from the treatment gas, e.g., charged treatment radicals, towards the substrate surface.

A tungsten gapfill material 708, shown in FIG. 7C, may be selectively deposited into the plurality of openings 705 according to the differential inhibition profile provided by a previous inhibition treatment. In one embodiment, the tungsten gapfill material 708 is formed using a low-stress chemical vapor deposition (CVD) process comprising concurrently flowing (co-flowing) a tungsten-containing precursor gas (also referred to herein as a process gas or a deposition gas), and a reducing agent into the processing region 121 and exposing the substrate 700 thereto. The tungsten-containing precursor and the reducing agent used for the tungsten gapfill CVD process may comprise any combination of the tungsten-containing precursors and reducing agents described herein. In some embodiments, the tungsten-containing precursor comprises WF₆, and the reducing agent comprises H₂, B₂H₆, SiH₄, or a combination thereof.

Here, the tungsten-containing precursor may be flowed into the processing region 121 at a rate of between about 50 sccm and about 1000 sccm, or more than about 50 sccm, or less than about 1000 sccm, or between about 100 sccm and about 900 sccm. The reducing agent is flowed into the processing region 121 at a rate of more than about 500 sccm, such as more than about 750 sccm, more than about 1000 sccm, or between about 500 sccm and about 10000 sccm, such as between about 1000 sccm and about 9000 sccm, or between about 1000 sccm and about 8000 sccm.

In some embodiments, the tungsten gapfill CVD process conditions are selected to provide a tungsten feature having a relativity low residual film stress when compared to other tungsten CVD processes. For example, in some embodiments, the tungsten gapfill CVD process includes heating the substrate to a temperature of about 250° C. or more, such as about 300° C. or more, or between about 250° C. and about 600° C., or between about 300° C. and about 500° C. The temperature of the substrate may be controlled and monitored by embodiments of the present disclosure. During the CVD process, the processing region 121 is typically maintained at a pressure of less than about 600 Torr, less than about 500 Torr, less than about 400 Torr, or between about 1 Torr and about 500 Torr, such as between about 1 Torr and about 450 Torr, or between about 1 Torr and about 400 Torr, or for example, between about 1 Torr and about 300 Torr.

In another embodiment, the tungsten gapfill material 708 may be deposited using an atomic layer deposition (ALD) process. The tungsten gapfill ALD process includes repeating cycles of alternately exposing the substrate 700 to a tungsten-containing precursor gas (also referred to herein as process gas or deposition gas) and a reducing agent and purging the processing region 121 between the alternating exposures. The tungsten-containing precursor and the reducing agent used for the tungsten gapfill ALD process may comprise any combination of the tungsten-containing precursors and reducing agents described herein. In some embodiments, the tungsten-containing precursor comprises WF₆, and the reducing agent comprises H₂.

Here, the tungsten-containing precursor and the reducing agent may each be flowed into the processing region 121 for a duration of between about 0.1 seconds and about 10 seconds, such as between about 0.5 seconds and about 5 seconds. The processing region 121 is typically purged between the alternating exposures by flowing an inert purge gas, such as argon (Ar), into the processing region 121 for a duration of between about 0.1 seconds and about 10 seconds, such as between about 0.5 seconds and about 5 seconds.

Exposing the substrate 700 to the tungsten-containing precursor may include flowing the tungsten-containing precursor into the processing region 121 from the deposition gas source 140 at a flow rate of between about 10 sccm and about 1000 sccm, such as between about 100 sccm and about 1000 sccm, between about 200 sccm and about 1000 sccm, between about 400 sccm and about 1000 sccm, or between about 500 sccm and about 900 sccm. Exposing the substrate 700 to the reducing agent may include flowing the reducing agent into the processing region 121 from the deposition gas source 140 at a flow rate of between about 500 sccm and about 10000 sccm, such as between about 500 sccm and about 8000 sccm, between about 500 sccm and about 5000 sccm, or between about 1000 sccm and about 4000 sccm.

In some embodiments, the tungsten gapfill ALD process includes heating the substrate to a temperature of about 250° C. or more, such as about 300° C. or more, or between about 250° C. and about 600° C., or between about 300° C. and about 500° C. The temperature of the substrate may be controlled and monitored by embodiments of the present disclosure. In some embodiments, the ALD process includes maintaining the processing region 121 at a pressure of less than about 150 Torr, less than about 100 Torr, less than about 50 Torr, for example, less than about 30 Torr, or between about 0.5 Torr and about 50 Torr, such as between about 1 Torr and about 20 Torr.

In other embodiments, the tungsten gapfill material 708 is deposited using a pulsed CVD method that includes repeating cycles of alternately exposing the substrate 700 to a tungsten-containing precursor gas and a reducing agent without purging the processing region 121. The processing conditions for the tungsten gapfill pulsed CVD method may be the same, substantially the same, or within the same ranges as those described above for the tungsten gapfill ALD process.

While the foregoing is directed to embodiments of the present disclosure, other and further embodiments of the disclosure may be devised without departing from the basic scope thereof, and the scope thereof is determined by the claims that follow.

What is claimed is:

1. A processing chamber for processing a substrate, comprising:
a chamber body;
a substrate support disposed within the chamber body and having a top surface;
a plurality of substrate lift pins disposed through the substrate support; and
a shadow ring lift assembly, the shadow ring lift assembly operable to raise and lower a shadow ring positioned above or level with the top surface of the substrate support.

2. The processing chamber of claim 1, wherein the shadow ring lift assembly is further operable to raise and lower the plurality of substrate lift pins.

3. The processing chamber of claim 2, wherein the shadow ring lift assembly further comprises:
a plurality of substrate lift pin holders, each substrate lift pin holder disposed around a base of a corresponding substrate lift pin of the plurality of substrate lift pins;
a plurality of shadow ring lift pins, each shadow ring lift pin disposed radially outward of a corresponding substrate lift pin holder and configured to contact a bottom surface of the shadow ring; and
a lift hoop configured to support each of the substrate lift pin holders.

4. The processing chamber of claim 3, further comprising a controller configured to cause, via a lift pin actuator, the lift hoop to move vertically to cause the plurality of substrate lift pins and the shadow ring lift pins to move vertically.

5. The processing chamber of claim 3, wherein each of the plurality of substrate lift pins includes a lift pin base configured to be disposed within one of the lift pin holders.

6. The processing chamber of claim 1, further comprising a showerhead disposed over the substrate support.

7. The processing chamber of claim 6, further comprising:
one or more gas sources configured to supply one or more deposition gases to a processing volume of the chamber body through the showerhead; and
one or more radical generators configured to supply one or more plasmas to the processing volume of the chamber body through the showerhead.

8. The processing chamber of claim 1, further comprising a lift pin actuator that is operable to cause the shadow ring lift assembly to raise and lower the shadow ring.

9. The processing chamber of claim 1, wherein the substrate support comprises a heater operable to heat the top surface of the substrate support.

10. The processing chamber of claim 1, further comprising:
a light pipe, wherein the light pipe is operable to collect electromagnetic radiation from an interior of the chamber body;
a sensor operable to sense a temperature of the top surface of the substrate support; and
a controller configured to:
estimate a temperature of the top surface of the substrate support, based on electromagnetic radiation collected by the light pipe from the top surface of the substrate support;
determine a transmissivity of the light pipe, based on a comparison of the estimated temperature of the top surface of the substrate support and the sensed temperature of the top surface of the substrate support; and
determine a temperature of the substrate, based on electromagnetic radiation collected by the light pipe from the substrate and the transmissivity.

11. The processing chamber of claim 10, wherein the controller is further configured to:
control one or more gas sources configured to supply one or more deposition gases to a processing volume of the chamber body through a showerhead, based on the temperature of the substrate; and
control one or more radical generators configured to supply one or more plasmas to the processing volume of the chamber body through the showerhead, based on the temperature of the substrate.

12. A method of processing a substrate, comprising:
supporting the substrate at a first distance from a heater of a processing chamber, wherein the first distance is based on a first temperature of the substrate;
performing, while the substrate is at the first temperature, a nucleation process on the substrate within the processing chamber;
supporting the substrate at a second distance from the heater, wherein the second distance is based on a second temperature of the substrate; and
performing, while the substrate is at the second temperature, a bulk process on the substrate within the processing chamber.

13. The method of claim 12, wherein:
the second distance is 0 millimeters (mm); and
the second temperature of the substrate is approximately equal to a temperature of the heater.

14. The method of claim 12, further comprising:
supporting, with one or more shadow ring lift pins, a shadow ring of the processing chamber above the substrate while performing the nucleation process on the substrate.

15. The method of claim 12, wherein the first temperature is between 285° C. and 315° C.

16. The method of claim 12, wherein the first temperature is between 298° C. and 302° C.

17. The method of claim 12, wherein the second temperature is between 435° C. and 465° C.

18. The method of claim 12, wherein the second temperature is between 448° C. and 452° C.

19. The method of claim 12, further comprising:
supporting a purge ring with the heater; and
supporting, with the purge ring, a shadow ring of the processing chamber while performing the bulk process.

20. A method of determining a temperature of a substrate in a processing chamber, comprising:
collecting, with a light pipe, electromagnetic radiation from a top surface of a substrate support disposed in the processing chamber;
sensing, with a temperature sensor within the substrate support, a temperature of the top surface of the substrate support;
estimating a temperature of the top surface of the substrate support, based on the electromagnetic radiation collected by the light pipe from the top surface of the substrate support;
determining a transmissivity of the light pipe, based on a comparison of the estimated temperature of the top surface of the substrate support and the sensed temperature of the top surface of the substrate support;
collecting, with the light pipe, electromagnetic radiation from the substrate in the processing chamber; and
determining the temperature of the substrate, based on the electromagnetic radiation collected by the light pipe from the substrate and the transmissivity.
